(19) United States
(12) Patent Application Publication
(10) Pub. No.: US 2025/0018440 A1
(43) Pub. Date: Jan. 16, 2025

(54) ALL-IN-ONE WAFER CLEANING MACHINE FOR MONOCRYSTALLINE SILICON PRODUCTION

(71) Applicant: TCL ZHONGHUAN RENEWABLE ENERGY TECHNOLOGY CO., LTD., Tianjin (CN)

(72) Inventors: Mengcheng QU, Tianjin (CN); Rui WU, Tianjin (CN); Zhijun WU, Tianjin (CN); Jingen CAO, Tianjin (CN); Zhengping LU, Tianjin (CN); Dongxiao ZHU, Tianjin (CN); Wei JIANG, Tianjin (CN); Liang YAN, Tianjin (CN); Chunjuan CHEN, Tianjin (CN); Xuejing MI, Tianjin (CN); Liwei JIANG, Tianjin (CN)

(73) Assignee: TCL ZHONGHUAN RENEWABLE ENERGY TECHNOLOGY CO., LTD., Tianjin (CN)

(21) Appl. No.: 18/548,574

(22) PCT Filed: Jul. 18, 2023
(86) PCT No.: PCT/CN2023/107811

§ 371 Date: Sep. 1, 2023

(30) Foreign Application Priority Data
Jun. 13, 2022 (CN) 202221465549.4

(51) Int. Cl. B08B 3/04; B08B 3/12; B08B 13/00

(52) U.S. Cl. CPC B08B 3/044; B08B 3/12; B08B 13/00

(57) ABSTRACT

An all-in-one wafer cleaning machine for monocrystalline silicon production includes: a circulation track disposed at a rear end of a cleaning equipment main body and fixed to the cleaning equipment main body; a horizontal moving device disposed at an outer side of the circulation track; a first motor fixedly installed at one end inside the horizontal moving device; a first transmission gear disposed at an output end of the first motor; a first fixed rod fixedly disposed at the other end of the horizontal moving device; a first fixed gear disposed at one end of the first fixed rod, wherein the first transmission gear and the first fixed gear are engaged with the circulating track; and a vertical track fixedly disposed at the horizontal moving device.

### CROSS-REFERENCE TO RELATED APPLICATION

This application claims priority to and the benefit of Chinese Patent Application No. 202221465549.4, filed in the China National Intellectual Property Administration on Jun. 13, 2022, the disclosure of which is hereby incorporated by reference in its entirety.

### TECHNICAL FIELD

The present disclosure relates to the technology field of monocrystalline silicon production, and more particularly to an all-in-one wafer cleaning machine for monocrystalline silicon production.

### BACKGROUND ART

Monocrystalline silicon is the most important semiconductor material in daily life, and it is also the most common material for manufacturing chips. After slicing silicon and then processing it, circuits are etched on a monocrystalline silicon wafer. Currently, the most common application of the monocrystalline silicon is production of solar power panels. However, after slicing and polishing processes, a surface of the monocrystalline silicon has many scratches and impurities that are invisible to the naked eye. It is necessary to perform corrosion and cleaning processes by a special liquid medicine to meet a use standard.

For example, in a China Granted Patent No. CN208527516U, an all-in-one automatic wafer cleaning machine includes a wafer inserting machine and a cleaning machine which are fixed to each other. The wafer inserting machine includes a basket lifting device, a wafer inserting device, and an integrated cassette loading device which are arranged sequentially. The cleaning machine includes a transmission device, a cleaning device, and a drying device. One side of the transmission device is provided with the cleaning device and the drying device. The cleaning device and the drying device are arranged sequentially.

The above-mentioned prior art realizes automatic cleaning of a silicon wafer to reduce the labor intensity of the staff. However, cleaning efficiency is low because the equipment cleaning method is monotonous. Furthermore, a monocrystalline silicon sliced wafer may be damaged when being shaken and cleaned. Accordingly, existing demands cannot be satisfied. To this end, we propose an all-in-one cleaning machine for a wafer in monocrystalline silicon production.

### SUMMARY OF DISCLOSURE

An objective of the present disclosure is to provide an all-in-one wafer cleaning machine for monocrystalline silicon production for solving the problems that the cleaning efficiency is low because the equipment cleaning method is monotonous and that the monocrystalline silicon sliced wafer may be damaged when being shaken and cleaned.

To realize the above-mentioned objective, the present disclosure provides the following technical solution. An all-in-one wafer cleaning machine for monocrystalline silicon production includes: a cleaning equipment main body; a drying chamber disposed at one side inside the cleaning equipment main body; a plurality of cleaning tanks disposed at the other side inside the cleaning equipment main body; a circulation track disposed at a rear end of the cleaning equipment main body and fixed to the cleaning equipment main body; a horizontal moving device disposed at an outer side of the circulation track; a first motor fixedly installed at one end inside the horizontal moving device; a first transmission gear disposed at an output end of the first motor; a first fixed rod fixedly disposed at the other end of the horizontal moving device; a first fixed gear disposed at one end of the first fixed rod, wherein the first transmission gear and the first fixed gear are engaged with the circulating track; and a vertical track fixedly disposed at the horizontal moving device.

Preferably, the all-in-one wafer cleaning machine for the monocrystalline silicon production further includes a base disposed below the cleaning equipment main body.

Preferably, in the all-in-one wafer cleaning machine for the monocrystalline silicon production, a surface of the circulation track is a tooth-like structure.

Preferably, in the all-in-one wafer cleaning machine for the monocrystalline silicon production, the circulation track is fixed to the cleaning equipment main body through a second fixing rod.

Preferably, in the all-in-one wafer cleaning machine for the monocrystalline silicon production, the vertical track is fixedly disposed at a middle of a top of the horizontal moving device.

Preferably, the all-in-one wafer cleaning machine for the monocrystalline silicon production further includes a lifting device disposed at an outer side of the vertical track.

Preferably, the all-in-one wafer cleaning machine for the monocrystalline silicon production further includes: a second motor fixedly disposed at one end inside the lifting device; a second transmission gear disposed at an output end of the second motor; a third fixed rod fixedly disposed at the other end inside the lifting device; and a second fixed gear disposed at one end of the third fixed rod, wherein the second transmission gear and the second fixed gear are engaged with the vertical track.

Preferably, the all-in-one wafer cleaning machine for the monocrystalline silicon production further includes: a connecting arm disposed at a front end of the lifting device, wherein a monocrystalline silicon wafer is disposed at one end of the connecting arm.

Preferably, the all-in-one wafer cleaning machine for the monocrystalline silicon production further includes: a first sliding groove formed at one end of the monocrystalline silicon wafer; and a second sliding groove formed at one end of the connecting arm, wherein the first sliding groove is inserted and matched with the second sliding groove.

Preferably, the all-in-one wafer cleaning machine for the monocrystalline silicon production further includes: an ultrasonic vibrator disposed at each of the cleaning tanks.

Preferably, in the all-in-one wafer cleaning machine for the monocrystalline silicon production, the ultrasonic vibrator is disposed at a middle of a bottom of each of the cleaning tanks.

Preferably, the all-in-one wafer cleaning machine for the monocrystalline silicon production further includes a water inlet and a water outlet respectively formed at an upper end and a lower end in a front surface of each of the cleaning tanks.

Preferably, the all-in-one wafer cleaning machine for the monocrystalline silicon production further includes a fan disposed at one end of the drying chamber.

Preferably, the all-in-one wafer cleaning machine for the monocrystalline silicon production further includes a heating wire disposed at one end of the fan.

Compared with the prior art, the advantageous effects of the present disclosure are as follows.

First, in the present disclosure, a cleaning track is disposed at a back surface of the cleaning device. When the cleaning work is completed, the staff takes off the monocrystalline silicon wafer, and the horizontal moving device returns to a starting position again through the circulation to perform the cleaning work again. As a result, the work efficiency is improved. In the meantime, since the monocrystalline silicon wafer needs to be cleaned with a variety of liquid medicines, the process of waiting for cleaning reduces the cleaning efficiency. Accordingly, multiple cleaning devices are disposed on the circulation track to ensure that multiple monocrystalline silicon wafers can be cleaned at the same time. The use efficiency is further improved.

Second, in the present disclosure, the bottom of the cleaning tank is provided with the ultrasonic vibrator, which generates numerous small bubbles to burst on the surface of the monocrystalline silicon wafer during use. The cleanliness of cleaning can be ensured while the structure of the monocrystalline silicon wafer is not affected. In the meantime, the qualified rate of the monocrystalline silicon wafer is also guaranteed during cleaning.

Third, in the present disclosure, pure water is used in the last cleaning tank of the device. The water is dried in the drying chamber after the cleaning process, so as to avoid excessive corrosion to affect the qualified rate of the monocrystalline silicon wafer because acidic or alkaline liquid medicine remains on the monocrystalline silicon wafer.

### BRIEF DESCRIPTION OF DRAWINGS

FIG. 1 illustrates a schematic diagram of an overall structure of the present disclosure.

FIG. 2 illustrates a top view of the overall structure of the present disclosure.

FIG. 3 illustrates a schematic diagram of an internal structure of a lifting device of the present disclosure.

FIG. 4 illustrates a side view of the overall structure of the present disclosure.

FIG. 5 illustrates a partially enlarged view of an area A in FIG. 4 of the present disclosure.

In the drawings:

1: cleaning equipment main body; 2: base; 3: circulation track; 4: heating wire; 5: monocrystalline silicon wafer; 6: lifting device; 7: water inlet; 8: water outlet; 9: ultrasonic vibrator; 10: second fixing rod; 11: fan; 12: drying chamber; 13: cleaning tank; 14: vertical track; 15: horizontal moving device; 16: first fixed rod; 17: second motor; 18: second transmission gear; 19: second fixed gear; 20: third fixed rod; 21: connecting arm; 22: first transmission gear; 23: first motor; 24: first fixed gear; 25: first sliding groove; 26: second sliding groove 26.

### DETAILED DESCRIPTION OF EMBODIMENTS

The following clearly and completely describes the technical solutions in the embodiments of the present disclosure with reference to the accompanying drawings in the embodiments of the present disclosure. Obviously, the described embodiments are some rather than all of the embodiments of the present disclosure.

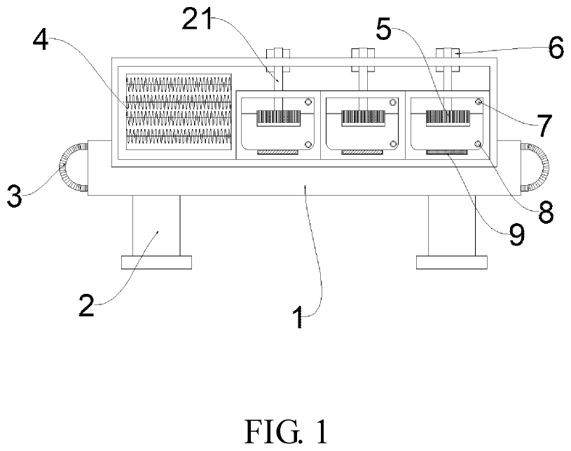

Please refer to FIGS. 1-5. In an embodiment provided by the present disclosure, an all-in-one wafer cleaning machine for monocrystalline silicon production includes a cleaning equipment main body 1. A base 2 is disposed below the cleaning equipment main body 1. A drying chamber 12 is disposed at one side inside the cleaning equipment main body 1, and three cleaning tanks 13 are disposed at the other side inside the cleaning equipment main body 1.

The all-in-one wafer cleaning machine for the monocrystalline silicon production further includes a circulation track 3 which is disposed at a rear end of the cleaning equipment main body 1. The circulation track 3 is fixed to the cleaning equipment main body 1 through a second fixing rod 10. A surface of the circulation track 3 is a tooth-like structure. A horizontal moving device 15 is disposed at an outer side of the circulation track 3. A first motor 23 is fixedly installed at one end inside the horizontal moving device 15. A first transmission gear 22 is disposed at an output end of the first motor 23. A first fixed rod 16 is fixedly disposed at the other end of the horizontal moving device 15. A first fixed gear 24 is disposed at one end of the first fixed rod 16. The first transmission gear 22 and the first fixed gear 24 are engaged with the circulating track 3. A vertical track 14 is fixedly disposed at a middle of a top of the horizontal moving device 15.

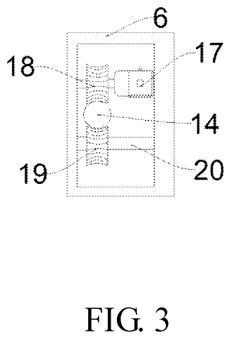

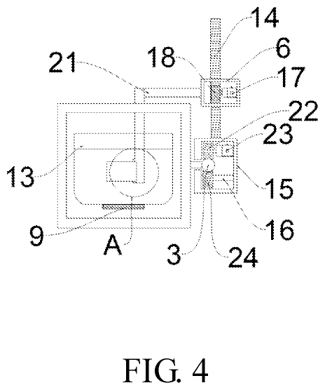

Please refer to FIG. 1, FIG. 3, and FIG. 4. A lifting device 6 is disposed at an outer side of the vertical track 14. A second motor 17 is fixedly disposed at one end inside the lifting device 6. A second transmission gear 18 is disposed at an output end of the second motor 17. A third fixed rod 20 is fixedly disposed at the other end inside the lifting device 6. A second fixed gear 19 is disposed at one end of the third fixed rod 20. The second transmission gear 18 and the second fixed gear 19 are engaged with the vertical track 14. In this way, up and down movements of a monocrystalline silicon wafer 5 are realized, and it is convenient to move the monocrystalline silicon wafer 5 to another cleaning tank 13.

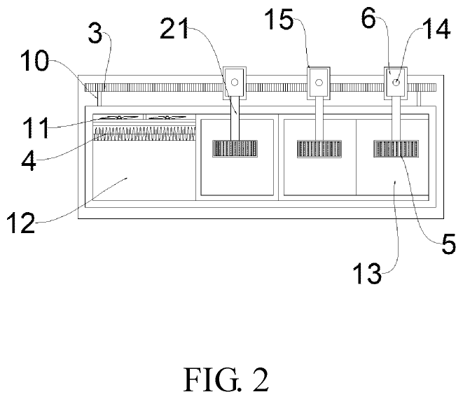

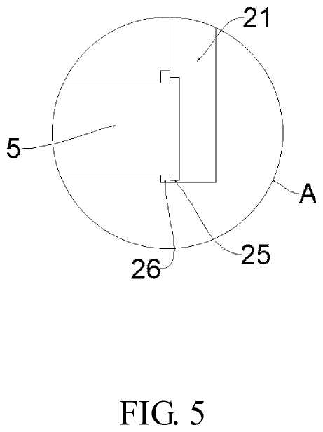

Please refer to FIG. 1, FIG. 2, FIG. 4, and FIG. 5. A connecting arm 21 is disposed at a front end of the lifting device 6. The monocrystalline silicon wafer 5 is disposed at one end of the connecting arm 21. A first sliding groove 25 is formed at one end of the monocrystalline silicon wafer 5. A second sliding groove 26 is formed at one end of the connecting arm 21. The first sliding groove 25 is inserted and matched with the second sliding groove 26. In this way, the monocrystalline silicon wafer 5 is fixed to the connecting arm 21, so that the monocrystalline silicon wafer 5 does not slip down during a cleaning process to protect the monocrystalline silicon wafer 5 from being damaged.

Please refer to FIG. 1 and FIG. 4. An ultrasonic vibrator 9 is disposed at a middle of a bottom of each of the cleaning tanks 13. In this way, cleaning effect is more efficient, and thus a number of repeated cleaning is reduced.

Please refer to FIG. 1. a water inlet 7 and a water outlet 8 are respectively formed at an upper end and a lower end in a front surface of each of the cleaning tanks 13. In this way, it is convenient to replace the liquid inside the cleaning tanks 13.

Please refer to FIG. 1 and FIG. 2. A fan 11 is disposed at one end of the drying chamber 12. A heating wire 4 is disposed at one end of the fan 11. In this way, the cleaned monocrystalline silicon wafer 5 is dried to avoid that adverse effects occur because water stains remain on the monocrystalline silicon wafer 5.

A working principle is as follows. During use, the monocrystalline silicon wafer 5 is fixed at one end of the connecting arm 21. Then, the first motor 23 drives the first transmission gear 22. The first transmission gear 22 is engaged, left and right, with gears on the circulation track 3 to drive the horizontal moving device 15 to move horizontally. In the meantime, the second motor 17 drives the second transmission gear 18, so that the lifting device 6 moves up and down on the vertical track 14 to drive the connecting arm 21 to move at the same time. By cooperation of the first motor 23 and the second motor 17, the monocrystalline silicon wafer 5 is moved to the cleaning tank 13. When the ultrasonic vibrator 9 is used, ultrasonic vibrations are generated to clean up impurities on the monocrystalline silicon wafer 5. Then, by cooperation of the first motor 23 and the second motor 17 again, the monocrystalline silicon wafer 5 is transported to the next cleaning tank 13 to complete the cleaning of the next stage. Finally, in the drying chamber 12, by cooperation of the heating wire 4 and the fan 11, the monocrystalline silicon wafer 5 is dried. After the cleaning work is completed, the monocrystalline silicon wafer 5 is removed. The first motor 23 drives the horizontal moving device 15 to return to a starting position through the bottom of the circulation track 3. Another monocrystalline silicon wafer is installed for cleaning work.

It is obvious to those skilled in the art that the present disclosure is not limited to the details of the above-mentioned exemplary embodiments, and that the present disclosure can be implemented in other specific forms without departing from the spirit or essential characteristics of the present disclosure. Therefore, no matter from all points of view, the embodiments should be regarded as exemplary and non-restrictive. The scope of the present disclosure is defined by the appended claims rather than the above description, so it is intended that all changes falling within the meaning and scope of equivalent requirements of the claims are included in the present disclosure. Any reference signs in the claims should not be construed as limiting the claims concerned.

1. An all-in-one wafer cleaning machine for monocrystalline silicon production, comprising:
a cleaning equipment main body;
a drying chamber disposed at one side inside the cleaning equipment main body;
a plurality of cleaning tanks disposed at the other side inside the cleaning equipment main body;
a circulation track disposed at a rear end of the cleaning equipment main body and fixed to the cleaning equipment main body;
a horizontal moving device disposed at an outer side of the circulation track;
a first motor fixedly installed at one end inside the horizontal moving device;
a first transmission gear disposed at an output end of the first motor;
a first fixed rod fixedly disposed at the other end of the horizontal moving device;
a first fixed gear disposed at one end of the first fixed rod, wherein the first transmission gear and the first fixed gear are engaged with the circulating track; and
a vertical track fixedly disposed at the horizontal moving device.

2. The all-in-one wafer cleaning machine for the monocrystalline silicon production of claim 1, further comprising a base disposed below the cleaning equipment main body.

3. The all-in-one wafer cleaning machine for the monocrystalline silicon production of claim 1, wherein a surface of the circulation track is a tooth-like structure.

4. The all-in-one wafer cleaning machine for the monocrystalline silicon production of claim 1, wherein the circulation track is fixed to the cleaning equipment main body through a second fixing rod.

5. The all-in-one wafer cleaning machine for the monocrystalline silicon production of claim 1, wherein the vertical track is fixedly disposed at a middle of a top of the horizontal moving device.

6. The all-in-one wafer cleaning machine for the monocrystalline silicon production of claim 1, further comprising a lifting device disposed at an outer side of the vertical track.

7. The all-in-one wafer cleaning machine for the monocrystalline silicon production of claim 6, further comprising:
a second motor fixedly disposed at one end inside the lifting device;
a second transmission gear disposed at an output end of the second motor;
a third fixed rod fixedly disposed at the other end inside the lifting device; and
a second fixed gear disposed at one end of the third fixed rod, wherein the second transmission gear and the second fixed gear are engaged with the vertical track.

8. The all-in-one wafer cleaning machine for the monocrystalline silicon production of claim 6, further comprising a connecting arm disposed at a front end of the lifting device, wherein a monocrystalline silicon wafer is disposed at one end of the connecting arm.

9. The all-in-one wafer cleaning machine for the monocrystalline silicon production of claim 8, further comprising:
a first sliding groove formed at one end of the monocrystalline silicon wafer; and
a second sliding groove formed at one end of the connecting arm, wherein the first sliding groove is inserted and matched with the second sliding groove.

10. The all-in-one wafer cleaning machine for the monocrystalline silicon production of claim 1, further comprising an ultrasonic vibrator disposed at each of the cleaning tanks.

11. The all-in-one wafer cleaning machine for the monocrystalline silicon production of claim 1, wherein the ultrasonic vibrator is disposed at a middle of a bottom of each of the cleaning tanks.

12. The all-in-one wafer cleaning machine for the monocrystalline silicon production of claim 1, further comprising a water inlet and a water outlet respectively formed at an upper end and a lower end in a front surface of each of the cleaning tanks.

13. The all-in-one wafer cleaning machine for the monocrystalline silicon production of claim 1, further comprising a fan disposed at one end of the drying chamber.

14. The all-in-one wafer cleaning machine for the monocrystalline silicon production of claim 1, further comprising a heating wire disposed at one end of the fan.
